(19) United States
(12) Patent Application Publication
(10) Pub. No.: US 2026/0233267 A1
(43) Pub. Date: Aug. 13, 2026

(54) SOLAR MODULE EXTERIOR DISASSEMBLING APPARATUS

(71) Applicant: WON KWANG S&T CO., LTD., Incheon (KR)

(72) Inventors: SANG HUN LEE, Incheon (KR); TAE HEUN LEE, Incheon (KR)

(21) Appl. No.: 19/157,041

(22) PCT Filed: Feb. 14, 2024
(86) PCT No.: PCT/KR2024/002110

§ 371 Date: Aug. 15, 2025

(30) Foreign Application Priority Data
Feb. 17, 2023 (KR) 10-2023-0021555

(51) Int. Cl. B09B 3/32; B09B 3/35; B09B 101/15

(52) U.S. Cl. CPC B09B 3/32; B09B 3/35; B09B 2101/15

(57) ABSTRACT

The solar module exterior disassembling apparatus is designed for efficiently removing the frame and junction box from solar modules. It features a positioning plate that supports the module from below and adjusts vertically. The apparatus employs foldable variable frame separation blades that transition between an inner position, within the module frame, and an outer position, facilitating frame detachment. These blades, capable of folding and unfolding, ensure close contact with the frame sides during operation. A pressing actuator, equipped with multiple pressing cylinders, exerts outward pressure to disassemble the module by advancing the separation blades. This system allows for precise and controlled removal of solar module exteriors, making it ideal for recycling and maintenance processes, enhancing the sustainability and efficiency of solar module management.

### BACKGROUND

### 1. Technical Field

The present disclosure relates to a solar module exterior (exterior structures such as a frame and a junction box) disassembling apparatus and, more particularly, to a solar module exterior disassembling apparatus that can more effectively disassemble a frame of a solar module and can also simultaneously disassemble a frame and a junction box.

This work was supported by Korea Environment Industry & Technology Institute (KEITI) through Prospective green technology innovation project, funded by Korea Ministry of Environment (MOE)(2022003170007).

### 2. Background Art

The development of clean energy that reduces environment pollution is being accelerated. Development of clean energy is in progress in various ways including national support projects. Clean energy technology variously includes not only a technology of managing produced power such as energy management, delivery, and storage, but a renewable energy technology that uses biomass, etc. Solar photovoltaic power generation, wind power generation, etc. that generate power using natural force without using the fossil fuel have been continuously studied as power production technologies.

In particular, solar photovoltaic power generation has been remarkably improved in power generation efficiency through continuous improvement of the technology since development, and accordingly, it is considered as a spotlighted alternative energy technology even at present. Solar photovoltaic power generation facilities are continuously increasing because there is the advantage that they can be easily applied even to places where conventional power generation facilities, etc. are difficult to install, they hardly cause environmental damage, and it is possible to use existing buildings, facilities, etc. when installing them.

However, a solar photovoltaic power generation facility also has a problem with maintenance because a solar cell has to be replaced and discarded when its lifespan is ended. In particular, as not only the number, but the application unit or area of solar photovoltaic power generation facilities are increased, it is required to replace and discard solar cells in large quantities. However, most solar photovoltaic power generation facilities are aggregate of photovoltaic modules formed by combining a solar cell in a frame. Further, since photovoltaic modules have a structure in which a glass plate, etc. are stacked, they are difficult to simply discard, which is a considerable problem in management of solar photovoltaic power generation facilities in a large scale.

For example, it may be required to separate first an interior panel including solar cells (an interior structure having a film type stack including a glass plate and solar cells stacked on the glass plate) from the exterior such as a frame when discarding a solar module. Further, when there are other exteriors (a junction box, etc.), it may be required to first remove the structures as well. If this work is not well completed, not only problems occur in the following processes, but also the entire process of discarding the solar module becomes complicated and retarded, so there is a need for an appropriate measure. As related prior art, there is Korean Patent Application Publication No. 10-2021-0083721 (Jul. 07, 2021).

### SUMMARY

An objective of the present disclosure is to provide a solar module exterior disassembling apparatus that can easily disassemble the exterior of a solar module, and particularly, to provide a solar module exterior disassembling apparatus that can more effectively disassemble a frame of a solar module and can also simultaneously disassemble the frame and a junction box.

The object of the present disclosure is not limited to those described above and other objects may be made apparent to those skilled in the art from the following description.

The present disclosure provides a solar module exterior disassembling apparatus for disassembling an exterior of a solar module in which a plate-shaped module body, which is composed of a glass plate and a film stack including solar cells stacked on the glass plate, and the exterior, which includes a frame surrounding the edge of the module body and a junction box attached to and protruding from the outer surface of the film stack, are coupled, which includes: a positioning plate supporting one surface of the module body from below the solar module and being able to move up and down; a plurality of frame separation blades disposed above the top contact plate and moving in parallel with a surface of the module body between a first position inside the frame and a second position outside the frame; and a pressing actuator including a plurality of pressing cylinders and pressing outward from the module body and disassembling the module body by moving forward the frame separation blades from the first position to the second position with the pressing cylinders, in which at least any one of the plurality of frame separation blades is configured by a foldable variable blade which is folded when moving backward to a first position and unfolded when moving forward to a second position to be closely attached to the entirety of one side of the frame.

The plurality of frame separation blades may be configured by four foldable variation blades, and gathered in a folding state inside the frame at the first position, and unfolded in a straight line when moving forward to the second position to be closely attached to four sides of the frame.

The foldable variation blade may include at least two rotation blades which is folded while rotating in a forward direction of the frame separation blade at the first position around an axis, and unfolded in the straight line while rotating in a reverse direction when contacting the frame.

A terminal of the rotation blade may be slid in the straight line to the outside from the inside of the frame while being closely attached to the frame to press a corner of the frame.

The apparatus may further include a rotation limitation portion that limits a maximum rotation angle of the rotation blade to fix the blade surface of the rotation blade to be parallel to the frame at one side of the rotation blade.

The foldable variation blade may further include a central fixation blade disposed between two rotation blades, and connected to each rotation blade by the axis.

The apparatus may further include a junction box separation blade disposed in at least any one of the plurality of frame separation blades, and including at least one junction box disassembling groove in which some of the frame separation blades are formed to protrude to the rear of the forward direction, and the junction box is inserted.

The apparatus may further include a gripper coupled to the frame separation blade, and including a movable claw coupled to the frame separation blade and holding and bringing the frame in contact with the frame separation blade.

One end portion of the movable claw may be coupled to a fixation shaft fixed to the frame separation blade, and pivot around the fixation shaft to be folded or unfolded.

The gripper may further include a sensor unit sensing the frame at one side of the frame separation blade and generating a sensing signal, and an actuation cylinder spaced apart from the fixation shaft, and hinge-coupled to a hinge shaft disposed in the movable claw, and pushing or pulling the hinge shaft by a fluid pressure according to the sensing signal to drive the movable claw.

According to the present disclosure, it is possible to conveniently perform, particularly, a work of disassembling an exterior (a frame, a junction box, etc.) that is a preceding process of the processes for discarding a solar module. According to the present disclosure, it is possible to simply and effectively disassemble the frame of a solar module and it is also possible to simultaneously disassemble the frame and a junction box, that is another exterior, through a single process. According to the present disclosure, up to an end portion of the corner of the frame may be uniformly pressed by the foldable variation blade, the frame is more easily disassembled, and since the frame is fixed in disassembling, it is possible to effectively prevent a safety accident that a metallic frame flies due to the elasticity thereof.

### BRIEF DESCRIPTION OF THE DRAWINGS

FIG. 1 is a perspective view of a solar module exterior disassembling apparatus according to an exemplary embodiment of the present disclosure;

FIG. 2 is a view showing a frame separation blade and a pressing actuator of the solar module exterior disassembling apparatus of FIG. 1 together with a solar module;

FIGS. 3 and 4 are operation views showing a structure and an operation of the frame separation blade of FIG. 2.

FIG. 5 is a view showing an operation of adjusting the position of a solar module by the solar module exterior disassembling apparatus of FIG. 1;

FIG. 6 is a plan view showing a layout of the frame separation blade and the pressing actuator of the solar module exterior disassembling apparatus of FIG. 5;

FIG. 7 is a layout view separately showing only the frame separation blade in the plan view of FIG. 6;

FIGS. 8 and 9 are operation views showing a frame separation process using a variation operation of the frame separation blade;

FIG. 10 is a plan view showing a modified example of the frame separation blade;

FIG. 11 is a plan view showing a layout of a gripper of the solar module exterior disassembling apparatus according to a second embodiment of the present disclosure;

FIG. 12 is a perspective view showing the gripper of FIG. 11;

FIGS. 13 and 14 are operation views showing the operation of the gripper of FIG. 12;

FIG. 15 is a plan view showing a junction box separation blade of the solar module exterior disassembling apparatus according to a third embodiment of the present disclosure; and

FIG. 16 is an operation view of the junction box separation blade of FIG. 15.

### DETAILED DESCRIPTION

The advantages and features of the present disclosure, and methods of achieving them will be clear by referring to the exemplary embodiments that will be described hereafter in detail with reference to the accompanying drawings. However, the present disclosure is not limited to the exemplary embodiments described hereafter and may be implemented in various ways, and the exemplary embodiments are provided to complete the description of the present disclosure and let those skilled in the art completely know the scope of the present disclosure and the present disclosure is defined by claims. Like reference numerals indicate the same components throughout the specification.

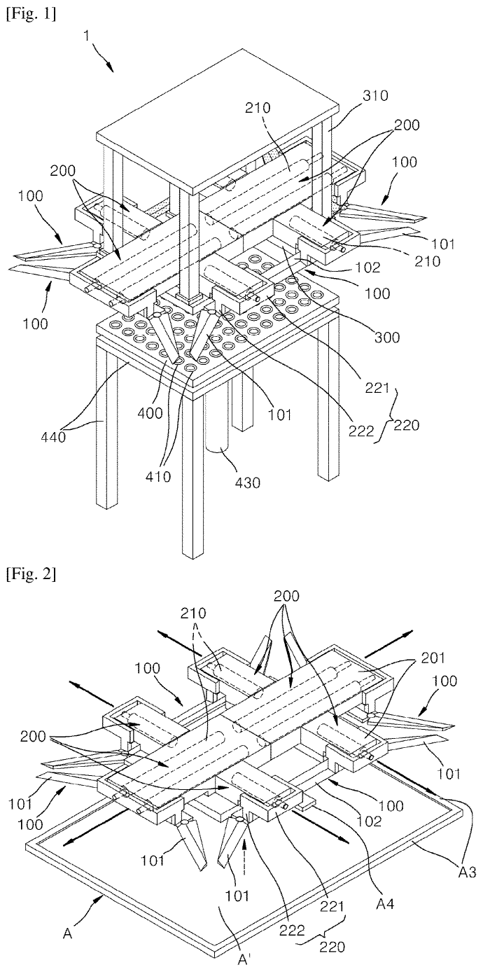

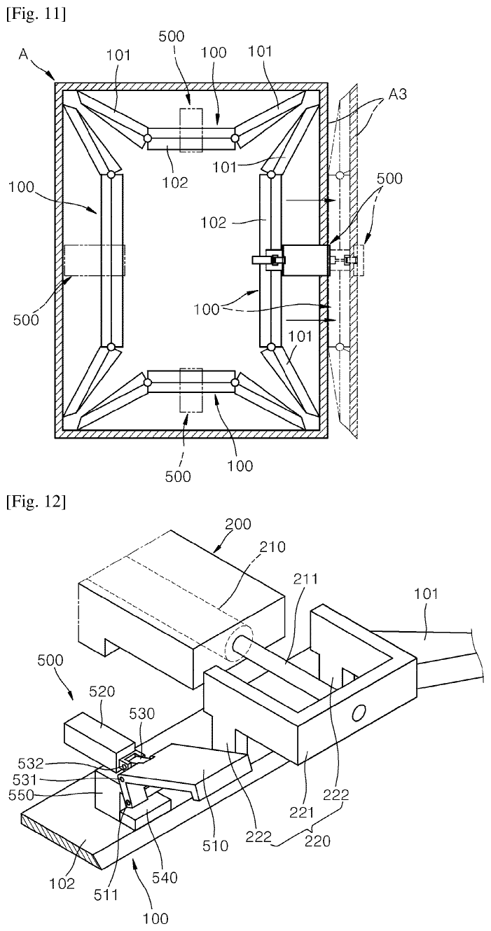

Hereafter, a solar module exterior disassembling apparatus according to the present disclosure is described in detail with reference to FIGS. 1 to 16. An exemplary embodiment of the present disclosure is described first in detail with reference to FIGS. 1 to 10 and second and third exemplary embodiments of the present disclosure are described in detail with reference to FIGS. 11 to 16.

FIG. 1 is a perspective view of a solar module exterior disassembling apparatus according to an exemplary embodiment of the present disclosure, and FIG. 2 is a view showing a frame separation blade and a pressing actuator of the solar module exterior disassembling apparatus of FIG. 1 together with a solar module.

Referring to FIGS. 1 and 2, a solar module exterior disassembling apparatus 1 according to the present disclosure disassembles a frame of a solar module by straightly driving a plurality of frame separation blades 100 (see FIG. 2). The frame separation blades 100 is slidably disposed above a positioning plate, and a positioning plate (see 400 in FIG. 1) under the top contact plate 300 moves up, thereby bringing the interior structure of a frame A3 (module body A′) of a solar module (see A in FIG. 2) in contact with the frame separation blades 100. The frame separation blade 100 moves horizontally along the module body A′ of the solar module A to disassemble the frame A3.

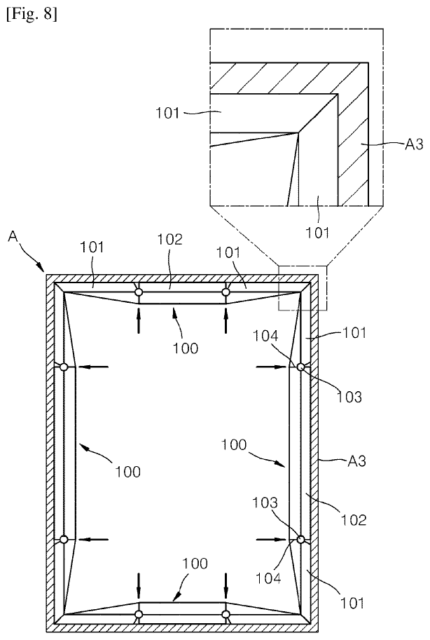

In particular, the frame separation blade 100 is configured by a foldable variation blade which is folded when moving backward inside the frame A3 and unfolded when moving forward outside the frame A3. Since the frame separation blade 100 configured by the foldable variation blade has a structure in which a rotation blade 101 is folded or unfolded while pivoting, when the frame separation blade 100 is folded at a retreating position, and then contacts the frames A3 upon moving forward, the frame separation blade 100 is unfolded to be closely attached to the entirety of one side of the frame A3. Therefore, the frame separation blade 100 is unfolded to effectively press even an edge portion (see an enlarged view of FIG. 8) of the frame A3 to which it is difficult to apply a pressure in the related art.

The solar module exterior disassembling apparatus 1 of the present disclosure is configured as follows. The solar module exterior disassembling apparatus 1 for disassembling the exterior of a solar module (see A in FIG. 2) in which a plate-shaped module body (see A′ in FIG. 2), which is composed of a glass plate and a film stack including solar cells stacked on the glass plate, and the exterior, which includes a frame (see A3 in FIG. 2) surrounding the edge of the module body and a junction box (see A4 in FIG. 2) attached to and protruding from the outer surface of the film stack, are coupled, includes: a positioning plate 400 supporting one surface of the module body from below the solar module and being able to move up and down; a plurality of frame separation blades 100 disposed above the positioning plate 400 and moving in parallel with a surface of the module body between a first position inside the frame and a second position outside the frame; and a pressing actuator 200 including a plurality of pressing cylinders 210 and pressing outward from the module body and disassembling the module body by moving forward the frame separation blades 100 from the first position to the second position with the pressing cylinders 210. In addition, at least any one of the plurality of frame separation blades 100 is configured by a foldable variable blade which is folded when moving backward to a first position and unfolded when moving forward to a second position to be closely attached to the entirety of one side of the frame.

In an exemplary embodiment of the present disclosure, in the solar module exterior disassembling apparatus 1, the plurality of frame separation blades 100 is configured by four foldable variation blades, and gathered in a folding state inside the frame at the first position (see FIG. 2), and unfolded in a straight line when moving forward to the second position to be closely attached to four sides of the frame (see FIG. 8). In the exemplary embodiment, the frame separation blade 100 is substantially the same as the foldable variation blade.

The foldable variation blade may include at least two rotation blades 101 which is folded while rotating in a forward direction of the frame separation blade 100 at the first position around an axis, and unfolded in the straight line while rotating in a reverse direction when contacting the frame. That is, each frame separation blade 100 may be formed by a foldable variation blade having a variation structure in which at least two rotation blades 101 are folded or unfolded.

However, since the technical spirit of the present disclosure need not be limited to the exemplary embodiment, the structure of the foldable variation blade may also be applied only to some of the frame separation blades 100.

The configuration, operation effect, etc. of the present disclosure are described hereafter in more detail on the basis of the exemplary embodiment of the present disclosure.

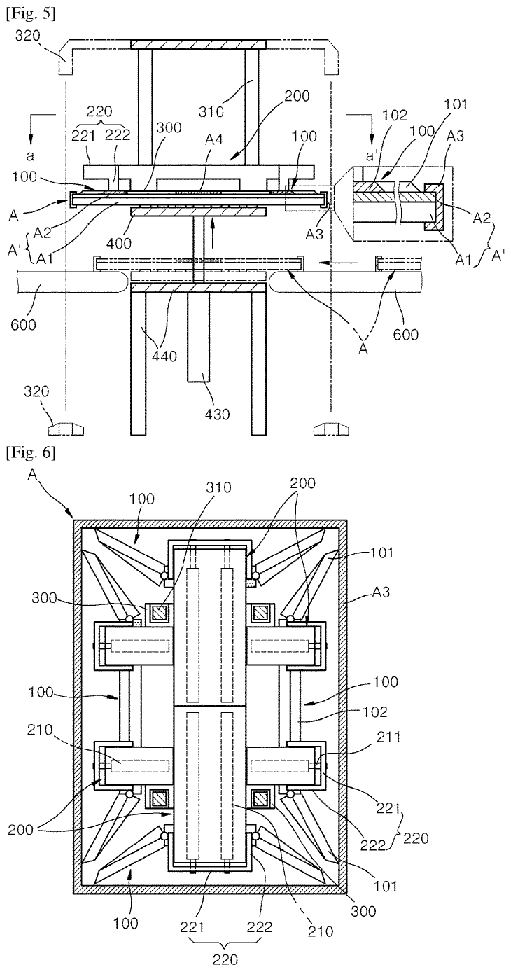

First, the solar module A and the exterior of the solar module that is the application target of the present disclosure are described with reference to FIG. 2. The solar module A may be formed by integrating a plurality of solar cells and may include a protector for integrating and protecting the solar cells. The solar module A includes an interior structure disposed in a panel shape inside a frame A3, the frame A3 surrounding the interior structure, and a junction box A4 protruding from a surface of the interior structure. The solar cells are included in the interior structure, and the frame A3 and the junction boxy A4 are exterior structures and correspond to the exterior of the solar module A stated in the present disclosure. The interior structure forms a plate-shaped module body A′ and the module body A′ includes a glass plate (see A1 in FIG. 5) and a film stack (see A2 in FIG. 5) including solar cells stacked on the glass plate A1. The interior structure of the solar module is the same as the module body A′ in the specification. The frame A3 serves to surround and protect the edge of the module body A′ and may be a metallic structure such as an aluminum bar.

The glass plate A1 of the module body A′, which is disposed on the front surface (i.e., a light-incident surface) of the solar module A in actual use, can serve to prevent the film stack A2 from being contaminated and maintain the shape of the film stack A2. The solar cells may be included in the film stack A2 and the film stack A2 may include, in addition to the solar cells, an encapsulation film, a back sheet, etc. that are disposed on both sides of the solar cells. The junction box A4 is a box-shaped structure disposed on the outer surface (i.e., the rear surface opposite the light-incident surface) of the film stack A2 and used for cable connection, etc.

In the exemplary embodiment, frame disassembling using the variation structure of the frame separation blade 100 will be primarily described. Simultaneous disassembling of the junction box and the frame by a disassembling structure of the junction box A4 will be described in detail in the third embodiment.

Referring to FIG. 1, the positioning plate 400 supports the solar module from below the solar module. The positioning plate 400 supports one surface of the module body (see A′ in FIG. 2) of the solar module from below the solar module and can move up and down. Referring to FIG. 2, the solar module A is disposed with the rear surface, on which the junction box A4 is positioned, up, and is mounted on the positioning plate 400 in this state. Accordingly, the surface supported by the positioning plate 400 is the surface on which the glass plate of the module body A′ is disposed and is the front surface (i.e., the light-incident surface) of the solar module. The positioning plate 400 may be coupled to a base 440 to be movable up and down, and the base may be various shapes of supporting structures that are supported on the ground. These supporting structures may be formed in various types, for example a type including a plurality of legs. For example, a lifting cylinder 430 that stretches and contracts up and down may be coupled between the base 440 and the positioning plate 400, and the positioning plate 400 can be moved up and down by the lifting cylinder 430. However, the present disclosure is not limited to the lifting cylinder 430 and may use other structures that can move up and down the positioning plate 400.

Referring back to FIG. 4, an outer support plate 420 may also be disposed at one side of the positioning plate 400. The outer support plate 420 may include a connection portion 421 which extends to the positioning plate 400, and the connection portion 421 may be detachably coupled to the positioning plate 421. The outer support plate 420 may be detachably coupled and used as necessary. For example, the outer support plate 420 may be disposed at a necessary point in order to reinforce a load applied to the outside of the positioning plate 400. However, when the load may be sufficiently supported only by the positioning plate 400, a disassembling task may be performed without using the outer support plate 420.

Referring to FIG. 2, a plurality of elastic portions 410 protruding upward may be formed on the top surface of the positioning plate 400 (i.e., the surface that comes in contact with the module body of the solar module). The elastic portions 410, for example, may be made of a natural or artificial rubber material and can elastically deform to come in contact with the contact surface of the module body. Accordingly, the module body can be effectively fixed even while disassembling is performed. The elastic portions 410, for example, may be made of ring shapes and may protrude from the top surface of the positioning plate 400. However, the elastic portions 410 may be deformed even to another form, e.g., another form such as a hemisphere in any degree. The elastic portions 410 may have an appropriate thickness and may be elastically deformed up and down by pressure, and can remove pressure applied to the glass plate by coming in contact with the glass plate (see A1 in FIG. 5) of the module body A′ through such elastic deformation. If necessary, besides the elastic portions 410, various structures that can increase friction at the top surface of the positioning plate 400 or can distribute pressure applied to the top surface of the positioning plate 400 may be applied.

The top contact plate 300 is disposed over the positioning plate 400. As shown in FIG. 1, the top contact plate 300 is disposed to face the positioning plate 400 over the positioning plate 400, and comes in contact with the other surface of the module body when the positioning plate 400 is moved up. The surface that the top contact plate 300 comes in contact with is the surface on which the junction box A4 of the module body A′ protrudes (the surface on which the film stack is formed), and accordingly, it is the rear surface (i.e., the opposite surface of the light-incident surface) of the solar module. Since the top contact plate 300 and the positioning plate 400 are disposed up and down to face each other, it is possible to firmly fix the module body, that is the internal structure of the solar module, by pressing both top and bottom of the module body.

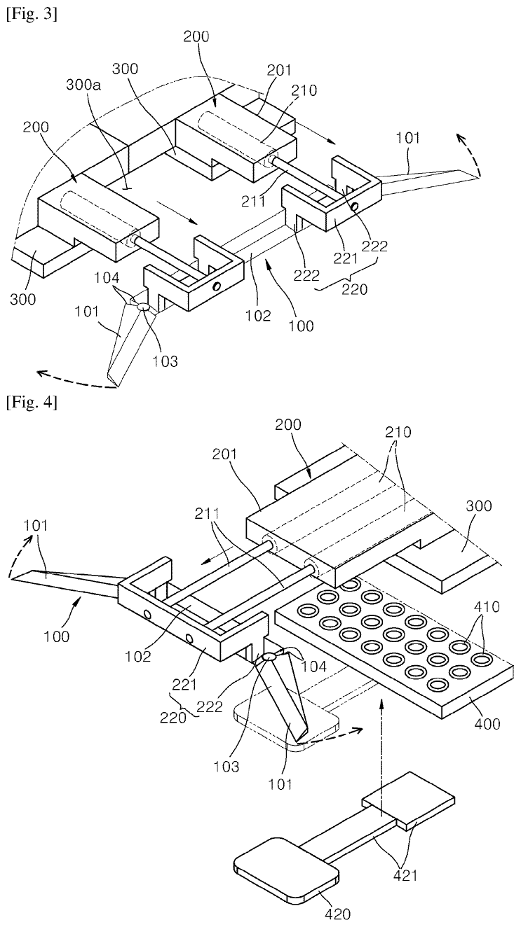

Momentarily referring to FIG. 3, the top contact plate 300 may be partially cut. A space portion 300a capable of accommodating the junction box A4 may be disposed at a cut portion. For example, when the junction box A4 is located at a central portion of the solar module A, a corresponding portion of the top contact plate 300 may be cut and the space portion 300a may be formed so as not to be overlapped with the junction box A4. Since the junction box may also be formed at another position, if the junction box is disposed at a position which is not interfered with the top contact plate 300, the space portion may not be formed. The top contact plate 300 is formed to be appropriately small within a limit to press the module body to provide a space in which the frame separation blade 100 is movable to the inside of the frame A3. A structure such as the elastic portion may also be formed at a lower portion of the top contact plate 300 as necessary.

Referring to FIG. 2, the frame separation blades 100 are disposed around the top contact plate 300. Since the frame separation blade 100 is also disposed above the positioning plate 300, the frame separation blade 100 may be disposed on the circumference of the top contact plate 300 located above the positioning plate 400. As shown in FIG. 2, the frame separation blades 100 can move straight in parallel with the surface of the module body A′ between the first position inside the frame A3 and the second side outside the frame A3 (see a straight-line arrow illustrated with a solid line of FIG. 2). The frame separation blades 100 shown in FIG. 2 may be close to each other by retracting as close as possible to the center of the solar module A, which may correspond to the first position of the frame separation blades 100 (i.e., the inside of the frame). The second position of the frame separation blades 100 may be a position where the frame separation blades 100 are moved forward outside the frame A3 in the directions of arrows, respectively, and then stopped. The frame separation blades 100 may have different movement distances and may not be symmetrically moved. However, in any case, the frame separation blades 100 are moved across the frame A3 from the inside to the outside of the frame A3, and necessarily cross the frame A3 surrounding the solar module A within the movement range. Accordingly, the first position may be understood as a position before the frame separation blades 100 cross the frame A3 and the second position may be understood as a position after the frame separation blades 100 cross the frame A3. The first position and the second position may be determined with respect to the frame A3 coupled to the solar module.

As described above, when the positioning plate (see reference numeral 400 of FIG. 1) moves up, the module body A′ is closely attached to the lower portion of the frame separation blade 100 and simultaneously, closely attached to the top contact plate 300.

Therefore, the module body A′ is pressed and fixed between the positioning plate 400 and the top contact plate 300. In this state, the frame A3 protruding up and down from the edge of the module body A′ at least partially crosses the frame separation blades 100. Accordingly, as shown in FIG. 2, when the frame separation blades 100 are moved forward from the inside to the outside of the frame A3, the frame A3 can be pressed and disassembled by the pressure. The frame separation blades 100, for example, may be made of a metallic material having high hardness and a blade surface may be machined to be pointed.

In particular, as shown, the frame separation blade 100 is configured by a foldable variation blade in which the rotation blade 101 is moved, and folded or unfolded. The frame separation blade 100 may be constituted by four blades corresponding to four sides of the frame A3, and all of four frame separation blades 100 may be configured by the foldable variation blades. Therefore, when each frame separation blade 100 is folded as shown in FIG. 2 when moving backward, and then moves forward, each frame separation blade 100 may be closely attached to the entirety of a side corresponding to the frame A3 in contact with the frame A3. Therefore, the frame separation blade 100 may substantially apply the pressure in contact with an entire portion of the frame A3. A structure and an actuation scheme of the frame separation blade 100 will be described below in more detail.

The pressing actuator 200 is connected to the frame separation blades 100 and provides a driving force to the frame separation blades 100. The pressing actuator 200 includes a plurality of pressing cylinders 210 connected to the frame separation blades 100, respectively, and the plurality of frame separation blades 100 are moved forward from the first position to the second position by the pressing cylinders 210. That is, the frame separation blades 100 are moved from the inside to the outside of the frame A3 coupled to the solar module, whereby the frame A3 is pressed outward from the module body A′ and disassembled. As shown in FIG. 2, the plurality of frame separation blades 100 are disposed to correspond to respective sides of the frame A3, and the plurality of pressing cylinders 210 may be connected to respective frame separation blades 100 in a direction crossing each side of the frame.

The pressing cylinders 210 may be driven by fluid pressure, and channels, a pump, etc. for supplying and returning fluid may be appropriately installed around the pressing cylinders 210. The facility related to supplying and returning fluid is not shown in the figures. The pressing actuator 200, for example, may include a body 201 having a space therein, and the pressing cylinders 210 may be disposed in the body 201. The top surface of the top contact plate 300 may be disposed in the space of the body 201, and the top contact plate 300 and the body 201 may be integrally formed. In this case, the structural strength can be increased.

Hereafter, the structure and the operation of the frame separation blade will be described in more detail with reference to FIGS. 3 and 4. FIGS. 3 and 4 are operation views showing a structure and an operation of the frame separation blade of FIG. 2.

Referring to FIGS. 3 and 4, the frame separation blades 100 may be connected to the pressing cylinders 210 through connection blocks 220, respectively. The connection block 220 includes a head 221 surrounding a piston 211 of the pressing cylinder 210, and a fixing plate 222 protruding from a side of the head 221 and fixing the frame separation blade 100 to the head 221. In particular, the fixing plate 222 is positioned behind the end of the piston 211 in the longitudinal direction of the piston 211, whereby the frame separation blade 100 is positioned further inside than the end of the piston 211. The configuration that the head 221 surrounds the piston 211 may mean that the head 221 at least partially has a portion longitudinally overlapping the piston 211. For example, the center portion of the head 221 may be fixed to the end of the piston 211 and both end portions thereof may longitudinally bend and overlap the piston 211 like a bracket. Although the head 221 is shown in this form in the figures, the head 221 is not necessarily limited thereto and may be changed in various forms.

The fixing plate 222 protrudes from the head 221 and fixes the frame separation blade 100 to the head 221. The fixing plate 222 may be integrated with the head 221 and can fix the frame separation blade 100 by being coupled to the frame separation blade 100 in various ways. The fixing plate 222 and the frame separation blade 100, for example, may be combined through various fastening methods such as welding, thread-fastening, fitting, alone or a combination thereof. For example, when the head 221 has a bracket shape, as described above, the fixing plate 222 may be formed at both ends of the bracket bending in the longitudinal direction of the piston 211. Accordingly, the fixing plate 222 is spaced apart from the end of the piston 211 and positioned behind the piston 211 in the longitudinal direction, thereby being able to fix the frame separation blade 100 at the same position. Such an example is shown in the figures.

As described above, since it is possible to position the frame separation blade 100 behind the end of the piston 211 in the longitudinal direction using the head 221 and the fixing plate 222, it is possible to determine the position of the frame separation blade 100 regardless of the stroke or the length of the piston 211. That is, the frame separation blade 100 is not necessarily positioned further outside than the end of the piston 211 and may be coupled to the connection block 220 and positioned further inside than the piston 211. Accordingly, even if the stroke of the piston 211 of the pressing cylinder 210 is long, it is possible to move the frame separation blade 100 to the inside the frame by adjusting the position of the connection block 220. For example, even if the end of the pressing cylinder 210 (which is the same as the end of the piston) protrudes outside the frame when the pressing cylinder 210 is fully contracted, the frame separation blade 100 can be positioned at the first position inside the frame by appropriately forming the head 221 and the fixing plate 222. Accordingly, it is possible to disassemble the frame by moving the frame separation blade 100 forward to the second position from the first position. By using the connection block 220 in this way, it is possible to freely use a pressing cylinder 210 that is long to be able to apply greater pressure.

A firm connection structure composed of the fixing plate 222 and the head 221 is also formed between the frame separation blade 100 and the pressing cylinder 210. The head 221 and the fixing plate 222, for example, may be an integrated metallic structure, and the end of the piston 211 may be firmly fixed by being tightened by a screw, etc. after passing through the head 221. Since the fixing plate 222 is coupled to the frame separation blade 100 by welding, etc., the connection structure can have strength sufficient to prevent twisting, etc. of the frame separation blade 100. As shown in the figures, a plurality of pressing cylinders 210 are connected in parallel to one frame separation blade 100 and at least two supporting points are secured to support the frame separation blade 100, whereby it is possible to prevent twisting of the frame separation blade 100 and increase the structural strength. Accordingly, it is possible to press one side of the frame with a plurality of pressing cylinders 210, which is advantageous in increasing pressure.

As described above, the frame separation blade 100 is configured by the foldable variation blade. The foldable variation blade (i.e., the frame separation blade) may include at least two rotation blades 101 which are rotated and folded in the forward direction of the frame separation blade 100 at the first position around the axis 103, and rotated in the reverse direction and unfolded in the straight line when contacting the frame. Actuation of the rotation blade 101 is illustrated in FIGS. 3 and 4 (see a dotted-line arrow).

That is, the frame separation blade 100 is formed by the foldable variation blade in which the rotation blade 101 is rotated and varied around the axis 103. The rotation blade 101 is folded in the forward direction of the frame separation blade 100 so as not to be interfered with another frame separation blade while moving backward to the first position inside the frame, and then rotated and unfolded in the reverse direction by the pressure while contacting the frame when the frame separation blade 100 moves forward to the second position outside the frame. As a result, a shape and a length of the frame separation blade 100 are also varied (see FIG. 8).

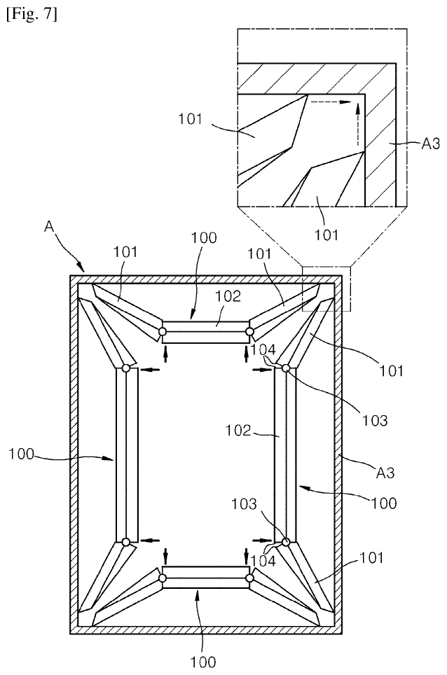

When the variation structure is used, the length of the frame separation blade 100 coincides with one side of the frame to uniformly press the entire frame. For example, when the frame is pressed by a fixed straight blade, the length cannot but be reduced in order to prevent an actuation range from being overlapped. Therefore, there is a problem in that a corner portion of the frame may not be pressed. In the present disclosure, the problem is resolved by the variation structure (i.e., the foldable variation blade) of the frame separation blade 100 (see FIGS. 7 and 8).

As necessary, a torsion spring (not shown) is coupled to the axis 103, so the rotation blade 101 may also be formed to be elastically folded in the forward direction. In this case, the rotation blade 101 may be unfolded by a pressing force applied by the frame when contacting the frame, and automatically folded by elasticity of the torsion spring when moving backward. Therefore, when the frame separation blades 100 move backward to the first position, the frame separation blades 100 may be more easily gathered inside the frame while being automatically folded.

The foldable variation blade (i.e., the frame separation blade) may further include a central fixation blade 102 disposed between two rotation blades 101, and connected to each rotation blade 101 by the axis 103. That is, as shown in FIGS. 3 and 4, the frame separation blade 100 may be formed in a structure in which two rotation blades 101 are rotatably coupled to both ends of the central fixation blade 102 by the axis 103. In this case, the frame separation blade 100 corresponds to a variation structure including at least two axes 103. However, there may be only axis 103 (see FIG. 10), and there may be two or more. The variation structure may be deformed in various forms including the axis. Since the axis 103 is formed to rotate the rotation blade 101 on the same plane as the blade surface of the frame separation blade 100, an axial line (not shown) penetrating a rotary center is disposed vertically to the blade surface of the frame separation blade 100. The axis 103 may be formed by a hinge axis configured by a hinge, for example. The variation structure of the frame separation blade 100 may be formed by such a scheme.

The fixation plate 222 may be coupled to a central fixation blade 102 of the frame separation blade 100. That is, the fixation plate 222 is coupled to the central fixation blade 102 to connect and fix the frame separation blade 100 to the pressing cylinder 210 via the connection block 220. However, it is not particularly necessary, and for example, it is also possible to connect the frame separation blade 100 and the pressing cylinder 210 in any degree by a scheme in which even though it is not the central fixation blade 102, a part (i.e., a part which is located at the rotary center of the rotation blade, but is not actually rotated) of a structure around the axis 103 is extended or deformed to be coupled to the fixation plate 222, that is, another form of fixation portion is formed, and the fixation portion and the fixation plate 222 are coupled.

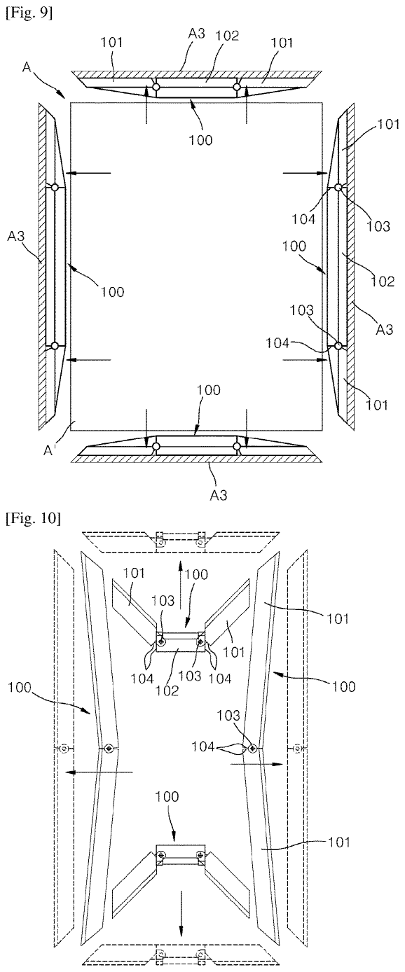

A rotation limitation portion 104 that limits a maximum rotation angle of the rotation blade 101 may be formed at one side of the rotation blade 101. The rotation limitation portion 104 adjusts a rotation range of the rotation blade 101 to fix the blade surface of the rotation blade 101 to be parallel to the frame. For example, the rotation limitation portion 104 may be formed in a structure in which an end portion adjacent to the axis 103 of the rotation blade 101 includes a cut portion cut at a predetermined angle to interrupt rotation at a predetermined angle or more. In this case, the rotation limitation portion 104 may limit the maximum rotation angle of the rotation blade 101 according to the cut angle of the cut portion, and allow the rotation blade 101 to be totally unfolded in the straight line, and fixed after being rotated at a predetermined angle (see FIGS. 8 and 9).

As necessary, the rotation limitation portion 104 may be formed at the end portion adjacent to the axis 103 of the central fixation blade 102, and in this case, may include a structure such as a plane, a protrusion, etc., which contacts the cut portion formed at the end portion of the central fixation portion 102. That is, when the rotation blade 101 is rotated at a predetermined angle, the rotation limitation portion 104 may be formed in various structures to interrupt rotation in contact with the rotation blade 101. The rotation limitation portion 104 need not be limited to a structure to limit or adjust the maximum rotation angle of the rotation blade 101.

When the frame separation blade 100 configured by the foldable variation blade is unfolded in the straight line as such, a total length coincides substantially with the length of the side of the frame (see FIG. 8). That is, a length between both ends is reduced in the folding state as shown in FIGS. 3 and 4, but when the frame separation blade 100 is unfolded in contact with the frame, the length increases with the same length as one side of the frame to be fully closely attached to the entirety of one side of the frame. Therefore, the entirety of the frame may be uniformly pressed while the frame separation blade 100 is closely attached up to the corner portion of the frame.

Hereafter, a frame disassembling operation using the variation structure of the frame separation blade will be described in more detail.

FIG. 5 is a view showing an operation of adjusting the position of a solar module by the solar module exterior disassembling apparatus of FIG. 1, and FIG. 6 is a plan view showing a layout of the frame separation blade and the pressing actuator of the solar module exterior disassembling apparatus of FIG. 5, FIG. 7 is a layout view separately showing only the frame separation blade in the plan view of FIG. 6, and FIGS. 8 and 9 are operation views showing a frame separation process using a variation operation of the frame separation blade. FIG. 5 is shown as a cross-section in order to reveal an internal structure of the solar module exterior disassembling apparatus, and FIG. 6 shows cross-section a-a′ of FIG. 5 in which a rail 600 is omitted.

Referring to FIG. 5, the solar module exterior disassembling apparatus 1 can disassemble a solar module A while being automatically supplied with the solar module A through the rail 600. The rail 600 may be installed at an appropriate position, and for example, may be disposed with the end facing the top of the base 440. The height of the rail 600 may be matched to the height of the top of the positioning plate 400 when moved down. The rail 600 may be composed of a rail 600 for being supplied with a solar module A (which may be the rail at the right side in FIG. 5), a rail 600 for discharging the module body A′ after the frame A3 is disassembled (which may be the rail at the left side in FIG. 5), etc. The rail 600, for example, may include a conveying structure such as a roller, a belt, etc. that can covey the solar module A.

The supplied solar module A is placed on the positioning plate 400, and the positioning plate 400 lifts the solar module A. Accordingly, the solar module A is lifted to come in contact with the upper structure, as shown in FIG. 5. As described above, since the top contact plate 300 is disposed over the positioning plate 400, the module body A′, that is the internal structure of the solar module A, is fixed in close contact between the positioning plate 400 and the top contact plate 300. In this process, the frame separation blades 100 disposed around the top contact plate 300 also come in contact with the module body A′, and as shown in FIG. 5, at least partially cross the frame A3 surrounding the module body A′. In this state shown in FIG. 5, all of frame separation blades 100 are at the first position inside the frame A3.

Here, the junction box A4 protruding from the top surface of the module body A′ is inserted into an empty space of the space portion (see reference numeral 300a of FIG. 3) not to be interfered with another structure. The junction box may be first removed as necessary, but may be disassembled simultaneously with the frame A3 by using the function box separation blade (see reference numeral 110 of FIG. 16) of the present disclosure as described below. The disassembling of the junction box will be described in detail in the third embodiment of the present disclosure.

In this process, pressure may be applied downward to the top contact plate 300 and this pressure can be supported by a supporting structure such as upper columns 310. That is, upper columns 310 may be perpendicularly connected to the top surface of the top contact plate 300 to support the pressure applied downward to the top contact plate 300 at the upper side. The lower ends of the upper columns 310 may be connected to the top contact plate 300 and the upper ends thereof may be connected to an upper supporting body 320 providing a supporting force. The upper supporting body 320 may be supported on the ground, and the structure or the shape is not necessarily specifically limited, so it is briefly shown with the detailed structure, etc. omitted. The upper supporting body 320 may be formed in various shapes that can support the upper structure including the top contact plate 300, the pressing actuator 200 disposed over the top contact plate 300, and the frame separation blades 200 connected to the pressing actuator 200. Although the upper supporting body 320 is supported on the ground in the figures, if necessary, the upper supporting body 320 may be supported on the ceiling of a workspace.

When the solar module A is fixed, as shown in FIG. 5, the frame separation blade 100 is located inside the frame A3 in a foldable state as shown in FIG. 6. That is, the plurality of frame separation blades 100 configured by the foldable variation blades 100 are gathered at the first position inside the frame A3 in the folding state. The frame separation blades 100 may move backward in advance before the positioning plate 400 moves up, and gathered inside as shown in FIG. 6. Since the rotation blades 101 may be folded while rotating in the forward direction in the retreating process, mutual interference is removed while at least some of the frame separation blades 100 are folded at the first position as shown in FIG. 6.

In FIG. 7, the layout of the frame separation blade 100 is more clearly shown. In FIGS. 7 to 9, another structure is arbitrarily omitted and shown in order to more specifically show a deformation operation of the frame separation blade 100. The layout of the frame separation blade 100 of FIG. 7 is exemplary, and the frame separation blade 100 may also be gathered at the center of the solar panel A within a movable range when moving backward to the inside of the frame. As such, even though the frame separation blades 100 are moved to cross each other, at least some of the blades are folded by the foldable variation structure, the blades are not interfered with each other even at the first position inside the frame A3.

When the pressing cylinder (see reference numeral 210 of FIG. 6) is driven in such a state, each frame separation blade 100 is moved to the second position outside the frame A3 from the first position inside the frame A3. FIG. 7 shows an example of the first position of the frame separation blade 100, and FIG. 9 shows an example of the second position of the frame separation blade 100. FIG. 8 shows a form in which the frame separation blade 100 moves forward to the second position as an intermediate position, and unfolded in contact with the frame A3.

As shown in FIG. 8, when each frame separation blade 100 moves forward toward the second position, each frame separation blade 100 is unfolded along each side of the frame A3 and is closely attached to each of four sides of the frame A3 by the variation structure. The rotation blade 101 is rotated in the reverse direction to the forward direction, and unfolded in the straight line in contact with the frame A3. Therefore, as shown, while lengths of both ends of the frame separation blades 100 are increased, the frame separation blades 100 are substantially closely attached to all of four sides of the frame A3 compactly.

Referring to the enlarged views of FIGS. 7 and 8, a terminal of the rotation blade 101 is slid in the straight line to the outside from the inside of the frame A3 while being closely attached to the frame A3 to reach up to a corner of the frame A3 (see the enlarge diagram of FIG. 7). Therefore, when the frame separation blade 100 is unfolded in contact with the frame A3, the terminal of the rotation blade 101 presses the corner of the frame A3 in contact with the corner of the frame A3 (see the enlarged view of FIG. 8). The corner is a portion corresponding to an apex where two sides of the frame A3 meet, and since lengths of general blades cannot but be shortened in order to avoid interference at the inside (the first position) of the frame A3, it is substantially impossible for the blades to press the corner. However, such a problem is resolved by the foldable variation structure (foldable variation blade) of the frame separation blade 100 which varies the shape and the length by rotating the rotation blade 101.

In an unfolding state as shown in FIG. 8, additional rotation of the rotation blade 101 is limited by the rotation limitation portion 104. Therefore, the blade surface is fixed in parallel to the frame A3. Since the blade surface of the central fixation blade 102 is also disposed in parallel to the frame A3, two rotation blades 101 and the entirety of the central fixation blade 102 therebetween are aligned in the straight line, and closely attached to the entirety of one side of the frame A3 compactly in the frame separation blade 100 in the unfolding state. Therefore, each frame separation blade 100 may uniformly apply all portions including the corner portion of the frame A3. As a result, unnecessary deformation, unintended breakage, etc. of the frame A3 by a pressure imbalance are reduced and the pressure is applied up to the corner to more effectively disassemble the frame A3.

For example, as shown in FIG. 9, the frame separation blades 100 move forward to the second position and compactly press four sides of the frame A3 to effectively separate the frame A3 into the side and the side. In the case of a general rectangular frame A3, most corners are bonded and connected, when the corners are pressed, it is possible to more easily separate the corners. However, since the length of the general blade is shortened not to be interfered inside as described above, there is a problem in that it is difficult to press the corner. In the present disclosure, since the rotation blade 101 is unfolded to compactly press up to the corner of the frame A3, it is more effective when disassembling the rectangular frame with the corners. As such, the frame A3 may be effectively disassembled by using the frame separation blade 100 configured by the foldable variation blade.

FIG. 10 is a plan view showing a modified example of the frame separation blade of FIG. 7.

Meanwhile, the variation structure of the frame separation blade 100 may also be deformed to another form. For example, as shown in FIG. 10, at least any one frame separation blade 100 may also be configured only by the rotation blade 101. That is, by a scheme in which two rotation blades 101 are directly coupled around the axis 103 to form the foldable variation blade. In this case, as described above, a partial structure (a portion located at the rotary center of the rotation blade, but not actually rotated) around the axis 103 is extended or deformed to be coupled to the fixation plate (see reference numeral 222 of FIG. 3) to form a fixation portion of yet another form, and the fixation portion and the fixation plate are coupled, the frame separation blade 100 and the pressing cylinder (see reference numeral 210 of FIG. 3) may be connected.

A deformation structure of the frame separation blade 100 is applicable according to various necessities. When the frame separation blade 100 is deformed, a movement range of the frame separation blade 100, the rotation angle, the movement scheme, etc., of the rotation blade 101 may be appropriately changed in response to the deformation of the frame separation blade 100. As an example, the frame separation blade 100 may deform the form of the foldable variation blade according to a size or a specification of the solar panel. The frame separation blade 100 is formed by the foldable variation blade including the rotation blade 101 as described above, but it is also possible to deform and apply an unfolding length, a layout of the axis, a thickness of the blade, the rotation angle of the rotation blade 101, etc., to a form to more effectively apply the pressure to the frame according to a situation. As such, the frame separation blade 100 configured by the foldable variation blade may be formed by various schemes, and the frame of the solar panel may be effectively disassembled.

Hereafter, the second embodiment of the present disclosure is described in detail with reference to FIGS. 11 to 14. For simple and clear description, the difference from the previous embodiment will be mainly described, and other configurations may refer to the previous description.

FIG. 11 is a plan view showing a layout of a gripper of the solar module exterior disassembling apparatus according to a second embodiment of the present disclosure, and FIG. 12 is a perspective view showing the gripper of FIG. 11. In FIG. 11, another structure is arbitrarily omitted in order to show the layout of the frame separation blade and the griper.

Referring to FIGS. 11 and 12, a solar module exterior disassembling apparatus according to the second embodiment of the present disclosure may further include a gripper 500 coupled to the frame separation blade 100. Other configurations are substantially the same as those of the above embodiment, so the description thereof is omitted. The gripper 500 may include a movable claw 510 coupled to the frame separation blade 100 and holding and bringing the frame of a solar module in contact with the frame separation blade 100 (see FIG. 12). The movable claw 510 can be folded or unfolded, and for example, may be rotated about a fixation shaft. The movable claw 510 is coupled at an end to a fixation shaft 511 fixed to the frame separation blade 100, so it can be folded or unfolded by rotating about the fixation shaft 511. The movable claw 510 may be in an unfolded state in FIG. 12, and when the movable claw 510 is folded by rotating about the fixation shaft 511, a frame can be retained between the frame separation blade 100 and the movable claw 510.

The gripper 500 may be installed in the central fixation blade 102 of the frame separation blade 100 as shown in FIG. 11, for example. However, the gripper 500 need not be limited thereto, and as necessary, it is also possible that the gripper 500 is disposed in the rotation blade 101 as necessary. FIG. 11 just shows a position at which the gripper 500 is enabled to be installed.

Referring to FIG. 12, the fixation shaft 511, for example, may be installed at a fixed structure that is fixed to the frame separation blade 100 such as a stand 550. An end of the movable claw 510 may be rotatably coupled to the fixation shaft 511 and another end may be bent. The movable claw 510 may have a hinge shaft 531 spaced apart from the fixation shaft 511 at a side, and can be supplied with a driving force through the hinge shaft 531. An operation cylinder 520 that is operated by fluid pressure may be connected to the hinge shaft 531, and the movable claw 510 can be operated by the operation of the operation cylinder 520. Though not shown, a channel for flow of fluid may be formed at a side of the operation cylinder 520, and a pump, etc. connected to the channel may be disposed at appropriate positions.

The structure of the gripper 500 is described in more detail hereafter. The gripper 500 may include a sensor unit 540 that senses the frame at a side of the frame separation blade 100 and generates a sensing signal, and the operation cylinder 520 spaced apart from the fixation shaft 511, coupled to the hinge shaft 531 disposed at the movable claw 510, and driving the movable claw 510 by pushing or pulling the hinge shaft 531 using fluid pressure in response to a sensing signal. Accordingly, the gripper 500 can automatically hold a frame on the basis of the sensing operation of the sensor unit 540. The operation cylinder 520 includes a piston that contracts and stretches and has a connection link 530 formed at the end of the piston 530, whereby it can be coupled to the hinge shaft 531. The connection link 530 has an end coupled to the hinge shaft 531 and the other end coupled to the connection shaft 532 at the end of the piston, thereby being able to function as a type of joint connecting the operation cylinder 520 and the movable claw 510.

The sensor unit 540 may include a contact sensor that senses a contact by an object, and if necessary, may include other sensors such as a proximity sensor that senses objects approaching within a predetermined range. The sensor unit 540 may be configured in various manners that can sense a frame. The sensor unit 540, for example, may be electrically connected to a controller that controls the operation cylinder 520 (e.g., a control structure including an electric control type pump that adjusts hydraulic pressure), thereby being able to automatically operate the operation cylinder 520. According to this configuration, it is possible to hold, fix, and more safely disassemble a frame as follows.

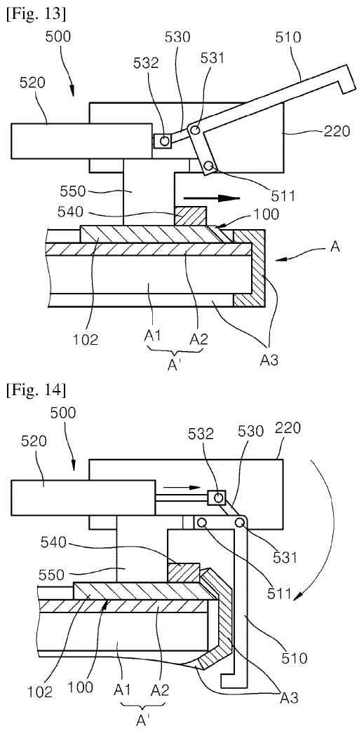

FIGS. 13 and 14 are operation views showing the operation of the gripper of FIG. 12.

The gripper may be maintained in the state shown in FIG. 13 before the sensor unit 540 senses the frame A3. That is, the operation cylinder 520 contracts and pulls the hinge shaft 531, and accordingly, the movable claw 510 is maintained in the unfolded state. Even though the frame separation blade 100 equipped with the gripper 500 is moved, the gripper 500 is maintained in the state unless the frame A3 is sensed. However, as shown in FIG. 14, when the sensor unit 540 senses the adjacent frame A3 by a contact, etc., the operation cylinder 520 pushes the hinge shaft 531, thereby quickly rotating the movable claw 510. Accordingly, the movable claw 510 folds and holds the frame A3 and the frame A3 is retained between the frame separation blade 100 and the movable claw 510. Accordingly, it is possible effectively prevent an accident that the frame A3 is flown outside due to pressure applied by the frame separation blade 100. When the module body A′ is separated from the frame A3 by the disassembling operation of the frame A3 (see FIGS. 7 to 9), the movable claw 510 can further fold because the rotation range increases, so it can more strongly fix the frame A3.

In this case, the connection link 530, which is a kind of double joint structure including the hinge shaft 531 and the connection shaft 532, can smoothly change the straight motion of the piston into a rotational motion of the movable claw 510. The shape of the movable claw 510 is not limited, and the movable claw 510 can be freely changed into any shapes other than that in the figures. If necessary, it is possible to more firmly fix the frame A3 by appropriately changing the degree of bending of the end, the shape, the entire length, etc. The grippers 500, as shown in FIG. 11, may be coupled to a plurality of different frame separation blades 100, respectively. Accordingly, it is possible to hold and fix a plurality of separated frames A3 using the grippers 500. Accordingly, even if greater pressure is applied by a pressing cylinder 210 having a relatively long stroke, disassembling can be very safely performed. The number of the gripper 500 disposed at the frame separation blade 100 may be decreased or increased, if necessary, and the positions of the grippers 500 can also be freely changed, so it is possible to more safely perform disassembling by appropriately installing the grippers 500. The frame may be disassembled more safely by applying the gripper 500 to the frame separation blade 100 by such a scheme.

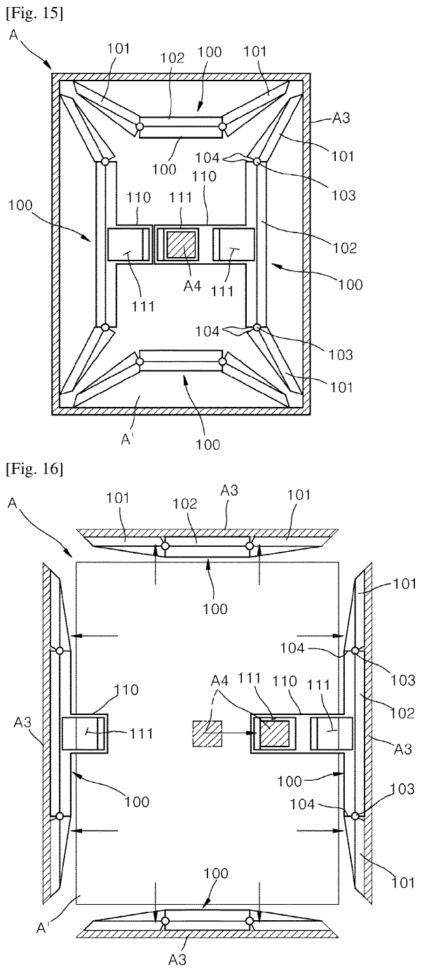

Hereafter, the third embodiment of the present disclosure will be described in detail with reference to FIGS. 15 and 16. For concise and clear description, a part different from the exemplary embodiment will be primarily described, and a description of all of the remaining part not separately mentioned is replaced with the above description.

FIG. 15 is a plan view showing a junction box separation blade of the solar module exterior disassembling apparatus according to a third embodiment of the present disclosure and FIG. 16 is an operation view of the junction box separation blade of FIG. 15. In FIGS. 15 and 16, another structure is arbitrarily omitted in order to show the layout of the frame separation blade and the junction box separation blade.

Referring to FIGS. 15 and 16, the solar panel exterior disassembling apparatus according to the third embodiment of the present disclosure may include a junction box separation blade 110 disposed at least any one of the frame separation blades 100. The junction box A4 may be disassembled together with the frame A3 by using the function box separation blade 110.

Referring to FIG. 15, the junction box separation blade 110 may be formed to protrude on the frame separation blade 100. In the function box separation blade 110, a part of the frame separation blade 100 may be formed to protrude to the rear of the forward direction, and at least one junction box disassembling groove 111 into which the junction box A4 is inserted may be formed inside the junction box separation blade 110. The junction box separation blade 110 may disassemble the function box A4 by a scheme of containing and moving the junction box A4 inside the junction box disassembling groove 111 The junction box separation blade 110 may protrude on the central fixation blade 102 among the frame separation blades 100, for example. The junction box separation blade 110 and the central fixation blade 102 may be formed integrally with each other.

The junction box separation blade 110 may be extended to the space portion (see reference numeral 300a of FIG. 3) between the top contact plates, for example. Since the junction box A4 is also located in the space portion as described above, the junction box A4 may be easily inserted into the junction box disassembling groove 111 formed in the junction box separation blade 110. For example, when the positioning plate (see reference numeral 400 of FIG. 5) moves up, the junction box A4 may be inserted into the junction box disassembling groove 111.

The position of the junction box A4 may depend on the type of solar panel, and the junction box separation blade 110 of the exemplary embodiment is more advantageous particularly in disassembling the junction box A4 disposed at the central portion inside the frame A3. Since the junction box separation blade 110 protrudes to the rear of the forward direction (i.e., in the retreating direction) of the frame separation blade 100, the junction box separation blade 110 may be used for processing the junction box A4 located in the retreating direction (e.g., at the central portion inside the frame) of the frame separation blade 100. The junction box disassembling groove 111 may be formed to penetrate the junction box separation blade 110.

The junction box separation blade 110 has a plurality of junction box disassembling grooves 111 to also selectively accommodate junction boxes A4 at different positions. The junction box disassembling groove 111 may be formed in a shape corresponding to the junction box, and formed in a polygonal shape such as a rectangular shape, etc. At least one blade surface is disposed on an inner surface of the junction box disassembling groove 111 to contact the junction box A4.

By such a structure, the junction box A4 is pressed and separated by the junction box separation blade 110 when the frame separation blade 100 moves as shown in FIG. 16. Since the junction box A4 is contained in the junction box disassembling groove 111, the junction box A4 is disassembled simultaneously with the frame A3 by receiving the pressure in a movement direction of the junction box separation blade 110 when the junction box separation blade 110 moves. After disassembling, for example, the positioning plate (see reference numeral 400 of FIG. 5) is moved down to discharge the junction box A4, and when the frame separation blade 100 is sufficiently moved forward to the outside by adjusting a stroke of the pressing cylinder, the junction box A4 may also be discharged by exposing the junction box disassembling groove 111 to the outside of the module body A′. By such a scheme, the junction box separation blade 110 is formed in the frame separation blade 100 to simultaneously disassemble the frame and the junction box.

Although exemplary embodiments of the present disclosure were described above with reference to the accompanying drawings, those skilled in the art would understand that the present disclosure may be implemented in various ways without changing the necessary features or the spirit of the prevent disclosure. Therefore, the exemplary embodiments described above are only examples and should not be construed as being limitative in all respects.

This invention presents a highly efficient solar module exterior disassembly apparatus, tailored for the renewable energy sector, particularly in solar module recycling and maintenance. Its innovative design, featuring foldable variable blades and a pressing actuator, allows for precise and damage-free removal of frames and junction boxes from solar modules, enhancing the recovery of valuable materials. The inclusion of rotation limitation portions and a gripper with a sensor unit ensures accuracy and safety in operation, making this apparatus a crucial tool for solar recycling facilities. Its ability to adapt to different module sizes and configurations underscores its versatility, offering significant cost savings and environmental benefits by promoting the circular economy within the solar industry.

1. A solar module exterior disassembling apparatus for disassembling an exterior of a solar module in which a plate-shaped module body, which is composed of a glass plate and a film stack including solar cells stacked on the glass plate, and the exterior, which includes a frame surrounding the edge of the module body and a junction box attached to and protruding from the outer surface of the film stack, are coupled, the solar cell exterior disassembling apparatus comprising:
a positioning plate configured for supporting one surface of the module body from below the solar module and being able to move up and down;
a plurality of frame separation blades disposed above the top contact plate and configured for moving in parallel with a surface of the module body between a first position inside the frame and a second position outside the frame; and
a pressing actuator including a plurality of pressing cylinders and configured for pressing outward from the module body and disassembling the module body by moving forward the frame separation blades from the first position to the second position with the pressing cylinders,
wherein at least any one of the plurality of frame separation blades is configured by a foldable variable blade which is folded when moving backward to a first position and unfolded when moving forward to a second position to be closely attached to the entirety of one side of the frame.

2. The apparatus of claim 1, wherein the plurality of frame separation blades is configured by four foldable variation blades, and gathered in a folding state inside the frame at the first position, and unfolded in a straight line when moving forward to the second position to be closely attached to four sides of the frame.

3. The apparatus of claim 1, wherein the foldable variation blade includes at least two rotation blades which is folded while rotating in a forward direction of the frame separation blade at the first position around an axis, and unfolded in the straight line while rotating in a reverse direction when contacting the frame.

4. The apparatus of claim 3, wherein a terminal of the rotation blade is configured to be slid in the straight line to the outside from the inside of the frame while being closely attached to the frame to press a corner of the frame.

5. The apparatus of claim 3, further comprising:
a rotation limitation portion configured to limit a maximum rotation angle of the rotation blade to fix the blade surface of the rotation blade to be parallel to the frame at one side of the rotation blade.

6. The apparatus of claim 3, wherein the foldable variation blade further includes a central fixation blade disposed between two rotation blades, and connected to each rotation blade by the axis.

7. The apparatus of claim 1, further comprising:
a junction box separation blade disposed in at least any one of the plurality of frame separation blades, and including at least one junction box disassembling groove in which some of the frame separation blades are formed to protrude to the rear of the forward direction, and the junction box is inserted.

8. The apparatus of claim 1, further comprising:
a gripper coupled to the frame separation blade, and including a movable claw coupled to the frame separation blade and holding and bringing the frame in contact with the frame separation blade.

9. The apparatus of claim 8, wherein one end portion of the movable claw is coupled to a fixation shaft fixed to the frame separation blade, and is configured to pivot around the fixation shaft to be folded or unfolded.

10. The apparatus of claim 9, wherein the gripper further includes a sensor unit configured for sensing the frame at one side of the frame separation blade and generating a sensing signal, and
an actuation cylinder spaced apart from the fixation shaft, and hinge-coupled to a hinge shaft disposed in the movable claw, and configured for pushing or pulling the hinge shaft by a fluid pressure according to the sensing signal to drive the movable claw.
